(19) United States
(12) Patent Application Publication
(10) Pub. No.: US 2012/0060912 A1
(43) Pub. Date: Mar. 15, 2012

(54) METHOD OF FORMING CONDUCTIVE ELECTRODE STRUCTURE AND METHOD OF MANUFACTURING SOLAR CELL WITH THE SAME, AND SOLAR CELL MANUFACTURED BY THE METHOD OF MANUFACTURING SOLAR CELL

(75) Inventors: Su Hwan Cho, Seoul (KR); Dong Hoon Kim, Gyeonggi-do (KR); Byung Ho Jun, Gyeonggi-do (KR); Kyoung Jin Jeong, Gyeonggi-do (KR)

(73) Assignee: SAMSUNG Electro-Mechanics Co., Ltd.

(21) Appl. No.: 13/227,046

(22) Filed: Sep. 7, 2011

(30) Foreign Application Priority Data
Sep. 10, 2010 (KR) 10-2010-0088949

(51) Int. Cl. H01L 31/18; H01L 31/0236; H01L 21/288

(52) U.S. Cl. 136/256; 438/612; 438/98; 257/E21.174; 257/E31.125

(57) ABSTRACT

The present invention provides a method of forming a conductive electrode structure including: applying a conductive paste on a substrate; forming a conductive pattern having an outwardly convex shape by heat-treating the conductive paste; and forming a solder layer to conformally cover the conductive pattern.

### CROSS-REFERENCE TO RELATED APPLICATIONS

This application claims the benefit under 35 U.S.C. Section 119 of Korean Patent Application Serial No. 10-2010-0088949, entitled “Method Of Forming Conductive Electrode Structure And Method Of Manufacturing Solar Cell With The Same, And Solar Cell Manufactured By The Method Of Manufacturing Solar Cell” filed on Sep. 10, 2010, which is hereby incorporated by reference in its entirety into this application.”

### BACKGROUND OF THE INVENTION

1. Field of the Invention

The present invention relates to a method of forming a conductive electrode structure and a method of manufacturing a solar cell with the same, and a solar cell manufactured by the method of manufacturing a solar cell, and more particularly, to a method of forming a conductive electrode structure capable of simplifying manufacturing processes and reducing manufacturing cost, and a method of manufacturing a solar cell with the same and a solar cell manufactured by the method of manufacturing a solar cell.

2. Description of the Related Art

In general, an electrode of a solar cell includes a silicon substrate having a light receiving surface and a conductive electrode structure disposed on the light receiving surface of the silicon substrate. The conductive electrode structure includes a positive electrode and a negative electrode which are selectively bonded to a PN impurity layer of the silicon substrate. In case of a front contact type solar cell in which the conductive electrode structure is disposed on the light receiving surface, as a line width of the conductive electrode structure decreases, an actual amount of light incident on the light receiving surface relatively increases. However, as the line width of the conductive electrode structure decreases, electrical resistance of the conductive electrode structure increases and thus characteristics as an electrode are deteriorated. Accordingly, a back contact type solar cell in which the conductive electrode structure is disposed on a non-light receiving surface of the silicon substrate has recently been developed.

In general, a conductive electrode structure of a back contact type solar cell forms a plating layer on a non-light receiving surface of a silicon substrate by performing a plating process using a metal layer as a seed layer after forming the metal layer on the silicon substrate. And, conductive patterns for positive and negative electrodes of the solar cell are formed by selectively etching the plating layer.

However, in case of forming a conductive electrode structure through a plating process, besides the plating process, a seed layer forming process for forming a plating layer, a resist pattern forming process for defining a non-forming region of a plating pattern during the plating process, a resist pattern removing process, and the like are separately added. Further, since a deposition process for forming a seed layer uses an expensive deposition apparatus such as a chemical vapor deposition apparatus or a physical vapor deposition apparatus, it becomes complex and thus cost is also greatly increased. Accordingly, a method of manufacturing a general back contact type solar cell has problems such as complex manufacturing processes and high manufacturing cost.

### SUMMARY OF THE INVENTION

The present invention has been invented in order to overcome the above-described problems and it is, therefore, an object of the present invention to provide a method of forming a conductive electrode structure capable of simplifying manufacturing processes and reducing manufacturing cost.

It is another object of the present invention to provide a method of manufacturing a solar cell capable of simplifying manufacturing processes and reducing manufacturing cost, and a solar cell manufactured by the same.

In accordance with one aspect of the present invention to achieve the object, there is provided a method of forming a conductive electrode structure including the steps of: applying a conductive paste on a substrate; forming a conductive pattern having an outwardly convex shape by heat-treating the conductive paste; and forming a solder layer to conformally cover the conductive pattern

In accordance with an embodiment of the present invention, the step of applying the conductive paste may be performed by using an inkjet printing method.

In accordance with an embodiment of the present invention, a paste including at least one of copper (Cu) and silver (Ag) may be used as the conductive paste.

In accordance with an embodiment of the present invention, the step of forming the solder layer may include the steps of applying a solder paste on the conductive pattern and heat-treating the solder paste.

In accordance with an embodiment of the present invention, the step of heat-treating the solder paste may be performed to melt the solder paste so that the solder paste is formed to be self-aligned with an upper surface of the conductive pattern.

In accordance with an embodiment of the present invention, the step of applying the solder paste may be performed by using a screen printing method, and the step of heat-treating the solder paste may include the step of reflowing the solder paste.

In accordance with an embodiment of the present invention, the method of forming a conductive electrode structure may include the step of forming a metal laminate pattern between the substrate and the conductive pattern, wherein the step of forming the metal laminate pattern may include the steps of forming a first metal layer on the substrate and forming a second metal layer on the first metal layer.

In accordance with another aspect of the present invention to achieve the object, there is provided a solar cell including: a substrate having a light receiving surface, a non-light receiving surface opposite to the light receiving surface, and a PN impurity layer formed on the non-light receiving surface; an insulating pattern which covers the non-light receiving surface and has a contact hole for exposing the PN impurity layer; and a conductive electrode structure provided on the non-light receiving surface, wherein the conductive electrode structure includes a metal laminate pattern bonded to the PN impurity layer through the contact hole, a conductive pattern which covers the metal laminate pattern and has an outwardly convex shape; and a solder layer which conformally covers the conductive pattern.

In accordance with an embodiment of the present invention, the conductive pattern may be formed by applying a conductive paste on the substrate.

In accordance with an embodiment of the present invention, the solder layer may be formed to be self-aligned with an upper surface of the conductive pattern.

In accordance with an embodiment of the present invention, the metal laminate pattern may include a first metal layer bonded to the PN impurity layer exposed through the contact hole and a second metal layer interposed between the first metal layer and the conductive pattern.

In accordance with an embodiment of the present invention, the first metal layer may be a layer for bringing the conductive pattern into ohmic contact with the PN impurity layer, and the second metal layer may be a diffusion barrier layer for preventing metal ions of the conductive pattern from being diffused into the substrate.

In accordance with an embodiment of the present invention, the PN impurity layer may include an N-type impurity diffusion region and a P-type impurity diffusion region disposed in a region except the N-type impurity diffusion region, and the conductive electrode structure may include a first electrode electrically bonded to the N-type impurity diffusion region through the contact hole and a second electrode electrically bonded to the P-type diffusion region through the contact hole.

In accordance with still another aspect of the present invention to achieve the object, there is provided a method of manufacturing a solar cell including the steps of: preparing a substrate having a light receiving surface and a non-light receiving surface opposite to the light receiving surface; forming a PN impurity layer on the non-light receiving surface of the substrate; forming an insulating pattern to cover the non-light receiving surface of the substrate; and forming a conductive electrode structure on the non-light receiving surface, wherein the step of forming the conductive electrode structure includes the steps of forming a metal laminate pattern bonded to the PN impurity layer through the contact hole, forming a conductive pattern which covers the metal laminate pattern and has an outwardly convex shape, and forming a solder layer to conformally cover the conductive pattern.

In accordance with an embodiment of the present invention, the step of forming the conductive pattern may include the steps of applying a conductive paste on the metal laminate pattern and heat-treating the conductive paste.

In accordance with an embodiment of the present invention, the step of applying the conductive paste may be performed by using an inkjet printing method.

In accordance with an embodiment of the present invention, at least one of a copper paste and a silver paste may be used as the conductive paste.

In accordance with an embodiment of the present invention, the step of forming the solder layer may include the steps of applying a solder paste on the conductive pattern and heat-treating the solder paste.

In accordance with an embodiment of the present invention, the step of heat-treating the solder paste may be performed to melt the solder paste so that the solder paste is formed to be self-aligned with an upper surface of the conductive paste.

In accordance with an embodiment of the present invention, the step of applying the solder paste may be performed by using a screen printing method, and the step of heat-treating the solder paste may include the step of reflowing the solder paste.

In accordance with an embodiment of the present invention, a paste including at least one of tin (Sn), silver (Ag), and nickel (Ni) may be used as the solder paste.

In accordance with an embodiment of the present invention, the step of forming the metal laminate pattern may include the steps of forming a first metal layer which covers the non-light receiving surface while filling the contact hole and forming a second metal layer on the first metal layer.

In accordance with an embodiment of the present invention, the step of forming the first metal layer may include the step of depositing an aluminum (Al) layer on the non-light receiving surface, and the step of forming the second metal layer may include the step of depositing a titanium tungsten (TiW) layer on the non-light receiving surface.

In accordance with an embodiment of the present invention, the step of preparing the substrate may include the step of preparing an N-type semiconductor substrate, and the step of forming the PN impurity layer may include the step of injecting P-type semiconductor impurity ions into the N-type semiconductor substrate.

In accordance with an embodiment of the present invention, the step of preparing the substrate may include the step of preparing a transparent plate having light transmittance.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a view showing some components of a solar cell in accordance with an embodiment of the present invention;

FIG. 2 is a flow chart showing a method of manufacturing a solar cell in accordance with the present invention; and

FIGS. 3 to 7 are views for explaining a process of manufacturing a solar cell in accordance with the present invention.

### DETAILED DESCRIPTION OF THE PREFERABLE EMBODIMENTS

Advantages and features of the present invention and methods of accomplishing the same will be apparent with reference to the following embodiments described in detail in conjunction with the accompanying drawings. However, the present invention is not limited to the following embodiments but may be embodied in various other forms. The embodiments are provided to complete the disclosure of the present invention and to completely inform a person with average knowledge in the art of the scope of the present invention. Like reference numerals refer to like elements throughout the specification.

Terms used herein are provided to explain embodiments, not limiting the present invention. Throughout this specification, the singular form includes the plural form unless the context clearly indicates otherwise. The terms “comprise” and/or “comprising” do not exclude the existence or addition of one or more different components, steps, operations, and/or elements.

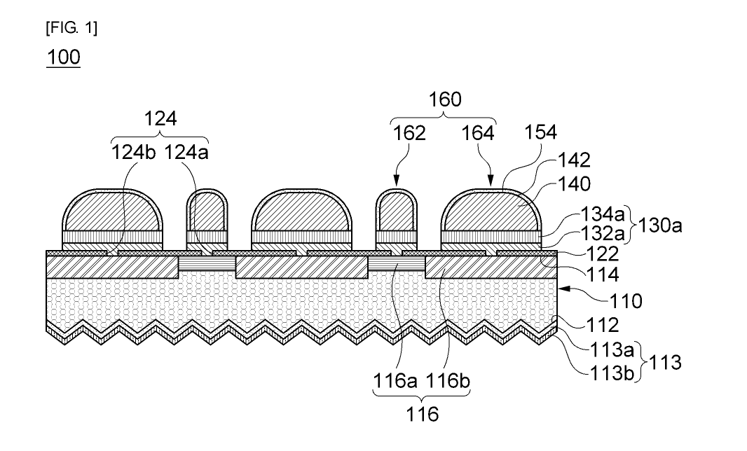

FIG. 1 is a view showing some components of a solar cell in accordance with an embodiment of the present invention. Referring to FIG. 1, a solar cell 100 in accordance with an embodiment of the present invention may include a substrate 110 and a conductive electrode structure 160 bonded on the substrate 110.

The substrate 110 may be a plate for manufacture of a solar cell. Accordingly, it may be preferred that a transparent plate having high light transmittance is used as the substrate 110. As an example, the substrate 110 may be a silicon wafer. As another example, the substrate 110 may be a glass substrate. As still another example, the substrate 110 may be a transparent plastic substrate.

The substrate 110 may have a light receiving surface 112 and a non-light receiving surface 114. The light receiving surface 112 may be a surface on which external light is incident, and the non-light receiving surface 114 may be a surface opposite to the light receiving surface 112.

The light receiving surface 112 may have an uneven structure. The uneven structure may be formed by performing a predetermined texturing treatment on the light receiving surface 112. The uneven structure may increase incidence efficiency of external light by increasing a surface area of the light receiving surface 112. An insulating layer 113 may be provided on the light receiving surface 112 to cover a surface of the uneven structure. The insulating layer 113 may include a silicon oxide layer 113a which covers the uneven structure with a uniform thickness and a silicon nitride layer 113b which covers the silicon oxide layer 113a. Further, a light reflective layer (not shown) may be further provided on the light receiving surface 112 to cover the uneven structure.

The substrate 110 may further include a PN impurity layer 116. The PN impurity layer 116 may be formed on the non-light receiving surface 114. The PN impurity layer 116 may include an N-type impurity diffusion region 116a and a P-type impurity diffusion region 116b formed in a region except the N-type impurity diffusion region 116a.

An insulating pattern 122 may be formed on the non-light receiving surface 114 of the substrate 110. The insulating pattern 122 may be one of an oxide layer and a nitride layer which covers the non-light receiving surface 114. As an example, the insulating pattern 122 may be a silicon oxide layer. The insulating pattern 122 may include a contact hole 124 which exposes the PN impurity layer 116. For example, the contact hole 124 may include a first contact hole 124a which exposes the N-type impurity diffusion region 116a and a second contact hole 124b which exposes the P-type impurity diffusion region 116b.

The conductive electrode structure 160 may be provided on the non-light receiving surface 114 of the substrate 110. In this case, the conductive electrode structure 160 may be an electrode of a back contact type solar cell in which positive and negative electrodes are provided on the non-light receiving surface 114.

The conductive electrode structure 160 may be provided on the non-light receiving surface 114 of the substrate 110. In this case, the conductive electrode structure 160 may be an electrode of a back contact type solar cell in which positive and negative electrodes are provided on the non-light receiving surface 114.

More specifically, the conductive electrode structure 160 may include a first electrode 162 and a second electrode 164 which are bonded to the non-light receiving surface 114. The first electrode 162 may be bonded to the N-type impurity diffusion region 116a to be used as a negative electrode of the solar cell 100, and the second electrode 164 may be bonded to the P-type impurity diffusion region 116b to be used as a positive electrode of the solar cell 100. For this, the first electrode 162 may be bonded to the N-type impurity diffusion region 116a through the first contact hole 124a, and the second electrode 164 may be bonded to the P-type impurity diffusion region 116b through the second contact hole 124b.

The first electrode 162 and the second electrode 164 may have a substantially similar structure but may be formed in different regions. For example, the first electrode 162 may be disposed on the N-type impurity diffusion region 116a, and the second electrode 164 may be disposed on the P-type impurity diffusion region 116b. In addition, the first electrode 162 and the second electrode 164 may be alternatively disposed on the non-light receiving surface 114. Each of the first electrode 162 and the second electrode 164 may include a metal laminate pattern 130a, a conductive pattern 140, and a solder layer 154.

The metal laminate pattern 130a may include a first metal pattern 132a and a second metal pattern 134a laminated on the first metal pattern 132a. The first metal pattern 132a may be a layer for bringing the first and second electrodes 162 and 164 into ohmic-contact with the PN impurity layer 116. For this, the first metal pattern 132a of the first electrode 162 may be configured to cover the insulating pattern 122 while filling the first contact hole 124a, and the first metal pattern 132a of the second electrode 164 may be configured to cover the insulating pattern 122 while filling the second contact hole 124b. Accordingly, the first metal pattern 132a of the first electrode 162 may be electrically bonded to the N-type impurity diffusion region 116a, and the first metal pattern 132a of the second electrode 164 may be electrically bonded to the P-type impurity diffusion region 116b.

The second metal pattern 134a may be a diffusion barrier layer for preventing metal materials of the first and second electrodes 162 and 164 from being diffused into the substrate 110. For this, the second metal pattern 134a may be interposed between the first metal pattern 132a and the conductive pattern 140 to prevent diffusion of metal ions from the conductive pattern 140 into the substrate 110.

The conductive pattern 140 may be disposed between the second metal pattern 134a and the solder layer 154. The conductive pattern 140 may be a major component used as a moving path of current in the conductive electrode structure 160.

The solder layer 154 may be a layer for electrical connection between the conductive pattern 140 and an external bonding object (not shown). The solder layer 154 may cover an upper surface 142 of the conductive pattern 140 with a uniform thickness.

The metal laminate pattern 132a, the conductive pattern 140, and the solder layer 154 may be made of various kinds of materials. For example, the first metal pattern 132a may be made of aluminum (Al), and the second metal pattern 134a may be made of titanium tungsten (TiW). The conductive pattern 140 may be made of copper (Cu) or silver (Ag). And, the solder layer 154 may be made of at least one of tin (Sn), silver (Ag), and nickel (Ni).

Meanwhile, the conductive pattern 140 may be formed on the substrate 110 by using an inkjet printing method. For example, the conductive pattern 140 may be formed by selectively applying a conductive paste including at least one of copper (Cu) and silver (Ag) on the metal laminate pattern 130a of the substrate 110 using an inkjet printer. And, the conductive pattern 140 may be formed by heat-treating the conductive paste. In this case, the conductive pattern 140 may have an outwardly convex shape due to coating characteristics of the inkjet printer. Accordingly, the solder layer 154, which covers the upper surface 142 of the conductive pattern 140 with a uniform thickness, may also have a convex shape.

Further, the solder layer 154 may be formed to be self-aligned with the upper surface 142 of the conductive pattern 140. For example, the solder layer 154 may be formed by heat-treating a solder paste after applying the solder paste on the upper surface 142 of the conductive pattern 140. In this case, the solder paste may be conformally formed only on the upper surface 142 of the conductive pattern 140. Accordingly, the solder layer 154 may have a structure surrounding the conductive pattern 140.

As described above, the solder cell 100 in accordance with an embodiment of the present invention may include the conductive electrode structure 160 provided on the non-light receiving surface 114 of the substrate 110, and the conductive pattern 140 of the conductive electrode structure 160 may be formed by an inkjet printing method. Accordingly, since the solar cell 100 in accordance with an embodiment of the present invention includes the conductive electrode structure 160 formed by an inkjet printing method, it can have the conductive electrode structure 160 of an outwardly convex shape, in comparison with a case of forming the conductive electrode structure by a plating process. Further, the conductive electrode structure 160 may include the solder layer 154 which is formed to be self-aligned with the upper surface 142 of the conductive pattern 140. In this case, the solder cell 100 may include the conductive pattern 140 of a convex shape and the solder layer 154 which is conformally formed on the upper surface 142 of the conductive pattern 140 and has a convex shape.

Accordingly, since the solar cell 100 in accordance with an embodiment of the present invention includes the conductive pattern 140 formed by an inkjet printing method and the solder layer 154 formed by being self-aligned with the conductive pattern 140, it can provide a structure capable of simplifying manufacturing processes and reducing manufacturing cost, in comparison with a case having the conductive pattern formed by a plating process.

Hereinafter, a method of manufacturing a solar cell in accordance with an embodiment of the present invention will be described in detail. Here, a repeated description of the above-described solar cell 100 in accordance with an embodiment of the present invention will be omitted or simplified. Further, since the method of manufacturing a solar cell includes a method of forming a conductive electrode structure, the method of forming a conductive electrode structure will not be separately described.

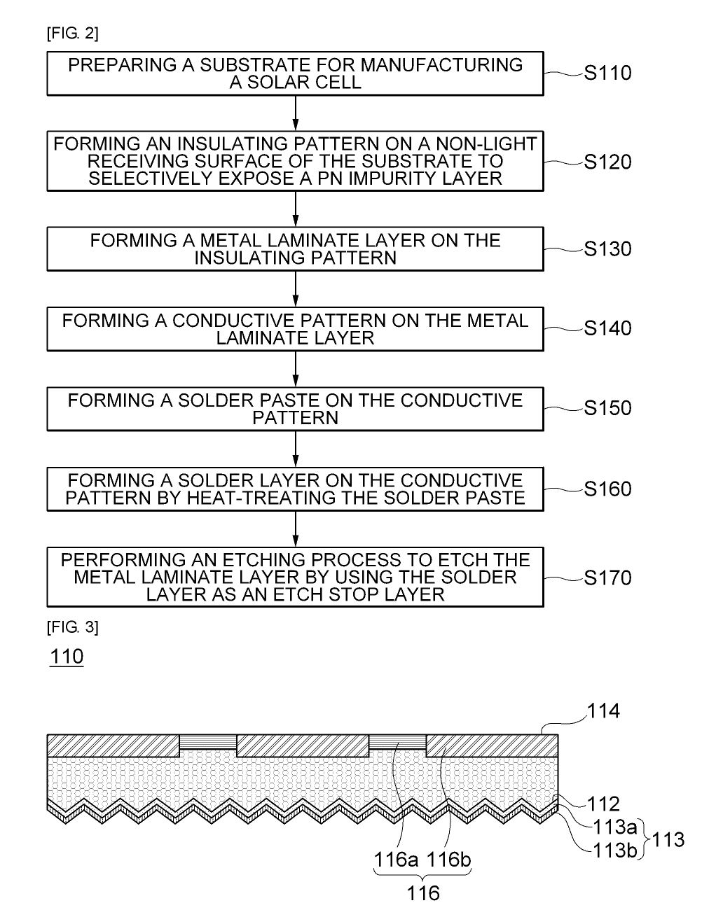

FIG. 2 is a flow chart showing a method of manufacturing a solar cell in accordance with the present invention, and FIGS. 3 to 7 are views for explaining a process of manufacturing a solar cell in accordance with the present invention.

Referring to FIGS. 2 and 3, a substrate 110 for manufacturing a solar cell may be prepared (S110). The substrate 110 may be one of various kinds of plates for manufacturing a solar cell. As an example, a silicon wafer may be prepared as the substrate 110. As another example, a glass substrate may be prepared as the substrate 110. As still another example, a plastic substrate may be used as the substrate 110.

The substrate 110 may have a light receiving surface 112 and a non-light receiving surface 114. The light receiving surface 112 may be a surface on which external light is incident, and the non-light receiving surface 114 may be a surface opposite to the light receiving surface 112.

A texturing treatment may be performed on the light receiving surface 112 of the substrate 110. Accordingly, an uneven structure may be formed on the light receiving surface 112 of the substrate 110. The uneven structure may increase a surface area of the light receiving surface 112. Accordingly, due to the uneven structure, light incidence on the light receiving surface 112 of the substrate 110 may be increased.

And, an insulating layer 113 may be formed to cover a surface of the uneven structure. The step of forming the insulating layer 113 may include the steps of forming a silicon oxide layer 113a to conformally cover the uneven structure and forming a silicon nitride layer 113b to cover the silicon oxide layer 113a.

Meanwhile, a PN impurity layer 116 may be formed on the non-light receiving surface 114 of the substrate 110. The step of forming the PN impurity layer 116 may include the step of injecting impurities into a silicon wafer. As an example, in case that the substrate 110 is a N-type semiconductor substrate, the step of forming the PN impurity layer 116 may be performed by selectively injecting P-type impurity ions into some regions of the N-type semiconductor substrate. At this time, the step of forming the PN impurity layer 116 may further include the step of injecting N-type impurity ions having a concentration higher than that of the N-type semiconductor substrate into a region except the region into which the P-type impurity ions are injected. Accordingly, the PN impurity layer 116, which consists of an N-type impurity diffusion region 116a and a P-type impurity diffusion region 116b formed in a region except the N-type impurity diffusion region 116a, may be formed on the non-light receiving surface 114 of the substrate 110.

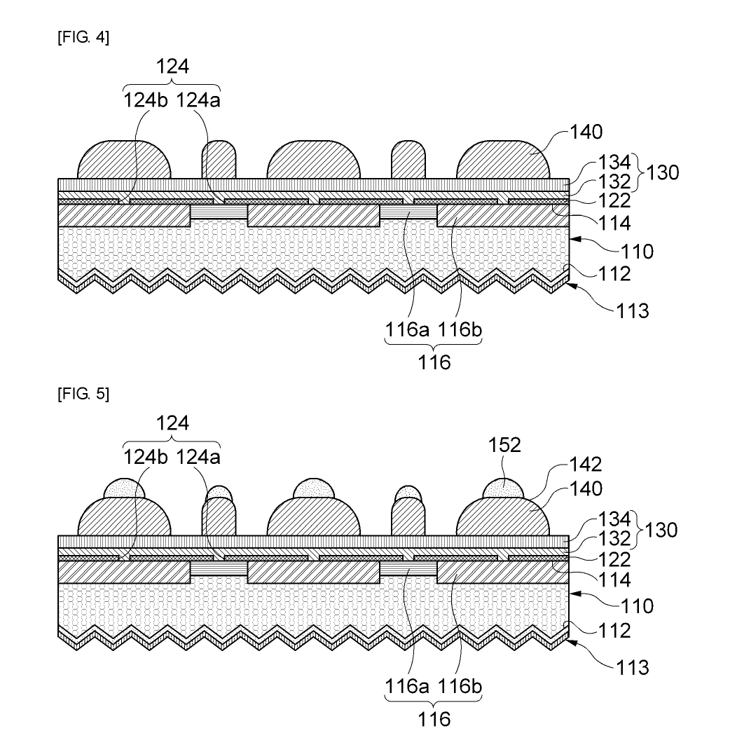

Referring to FIGS. 2 and 4, an insulating pattern 122 may be formed on the non-light receiving surface 114 of the substrate 110 to selectively expose the PN impurity layer 116 (S120). First, an insulating layer may be formed on the non-light receiving surface 114 of the substrate 110. The step of forming the insulating layer may include the step of forming an oxide layer or a nitride layer which covers the non-light receiving surface 114 with a uniform thickness. As an example, the insulating layer may be a silicon oxide layer.

And, a contact hole 124 may be formed in the insulating layer. The step of forming the contact hole 124 may include the step of forming a first contact hole 124a which exposes the N-type impurity diffusion region 116a and forming a second contact hole 124b which exposes the P-type impurity diffusion region 116b. Here, the step of forming the contact hole 124 may use various kinds of etching processes. As an example, the step of forming the contact hole 124 may be performed by using a photolithography process and a wet etching process.

A metal laminate layer 130 may be formed on the insulating pattern 122. For example, a first metal layer 132 may be formed to cover the insulating pattern 122 while filling the contact hole 124. The first metal layer 132 may be a layer for bringing a conductive electrode structure 160 of FIG. 7, which is to be formed in the following process, into ohmic contact with the substrate 110. As an example, the first metal layer 132 may be a layer made of aluminum (Al). And, a second metal layer 134 may be formed to cover the first metal layer 132. The second metal layer 134 may be a layer for preventing metal ions of the conductive electrode structure 160 from being diffused into the substrate 110. As an example, the second metal layer 134 may be a layer made of titanium tungsten (TiW).

Meanwhile, the step of forming the metal laminate layer 130 may be performed by various kinds of deposition processes. For example, the step of forming the first and second metal layers 132 and 134 may be performed by one of a chemical vapor deposition (CVD) process and a physical vapor deposition (PVD) process. As an example, the first and second metal layers 132 and 134 may be formed by performing at least one of a sputtering process and an evaporation process.

A conductive pattern 140 may be formed on the metal laminate layer 130 (S140). As an example, the step of forming the conductive pattern 140 may include the step of applying a conductive paste on the non-light receiving surface 114 of the substrate 110. The step of applying the conductive paste may be performed by performing an inkjet printing process on the substrate 110. As an example, the step of applying the conductive paste may include the step of selectively printing a paste of at least one of copper (Cu) and silver (Ag) using an inkjet printer.

Meanwhile, the conductive pattern 140 may be used as an electrode of a solar cell. Accordingly, it may be preferred that the conductive pattern 140 is made of a metal material having high electrical conductivity. As an example, the conductive pattern 140 may be a conductive line including copper (Cu). As another example, the conductive pattern 140 may be a conductive line including silver (Ag). However, a material of the conductive pattern 140 may not be limited to the above materials, and any material having enough electrical conductivity to be utilized as an electrode of a solar cell may be applied as the material of the conductive pattern 140.

Referring to FIGS. 2 and 5, a solder paste 152 may be formed on the conductive pattern 140 (S150). The step of forming the solder paste 152 may be performed by selectively applying a conductive paste on an upper surface 142 of the conductive pattern 140. As an example, the step of forming the solder paste 152 may be performed by using a screen printing method. Here, the step of coating the conductive paste may be performed by applying a metal paste including at least one of tin (Sn), silver (Ag), and nickel (Ni) on the conductive pattern 140.

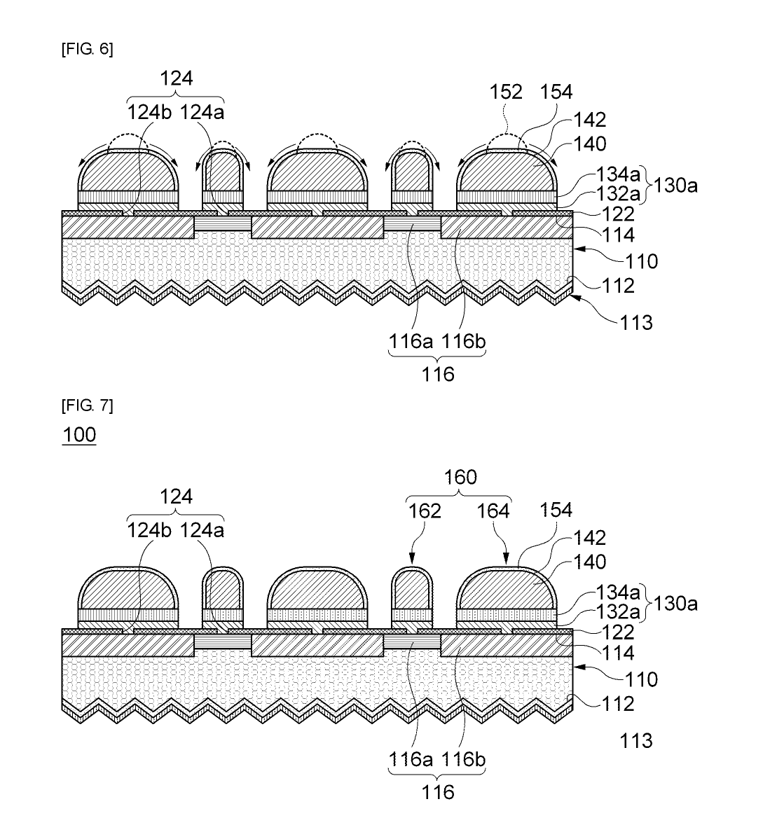

Referring to FIGS. 2 and 6, a solder layer 154 may be formed on the conductive pattern 140 by heat-treating the solder paste 152 (S160). For example, the solder paste 152 may be reflowed. Accordingly, the solder paste 152 may be melted and spread to selectively cover the upper surface 142 of the conductive pattern 140. Here, the solder paste 152 may be formed only on the upper surface 142 while being self-aligned with the upper surface 142 of the conductive pattern 140. Accordingly, the solder layer 154 may be formed to selectively conformally cover the upper surface 142 of the conductive pattern 140.

Referring to FIGS. 2 and 7, an etching process may be performed to etch the metal laminate layer 130 of FIG. 6 by using the solder layer 154 as an etch stop layer (S160). The etching process may be a wet etching process for sequentially etching the second metal layer 134 of FIG. 6 and the first metal layer 132 of FIG. 6 by using a predetermined etchant. Further, for formation of the conductive pattern 140, in case that a metal seed layer (not shown) is formed on the metal laminate layer 130, a process of etching the metal seed layer may be added.

Meanwhile, various kinds of chemicals may be used as the etchant. For example, in case that the second metal layer 134 is a layer made of titanium tungsten, an etchant including peroxide (H₂O₂) may be used as an etchant for etching the second metal layer 134. In case that the first metal layer 132 is a layer made of aluminum, an etchant including potassium hydroxide (KOH) may be used as an etchant for etching the first metal layer 132. Further, in case that the metal seed layer is formed, an etchant including sulfuric acid (H₂SO₄), phosphoric acid (H₃PO₄), and peroxide (H₂O₂) may be used as an etchant for etching the metal seed layer.

Through the above etching process, a metal laminate pattern 130a including a pattern in electrical contact with the N-type impurity diffusion region 116a of the substrate 110 and a pattern in electrical contact with the P-type impurity diffusion region 116b may be formed. Each metal laminate pattern 130a may have a structure in which a first metal pattern 132a formed by etching the first metal layer 132 and a second metal pattern 134a formed by etching the second metal layer 134 are sequentially laminated.

Through the above process, the conductive electrode structure 160, which consists of a first electrode 162 in electrical contact with the N-type impurity diffusion region 116a and a second electrode 164 in electrical contact with the P-type impurity diffusion region 116b, may be formed on the non-light receiving surface 114 of the substrate 110. Here, the conductive electrode structure 160 may consist of the metal laminate pattern 130a, the conductive pattern 140, and the solder layer 154 which are sequentially laminated on the non-light receiving surface 114 of the substrate 110.

As described above, the method of manufacturing a solar cell in accordance with an embodiment of the present invention may form the conductive electrode structure 160 bonded to the non-light receiving surface 114 of the substrate 110, and the conductive pattern 140 of the conductive electrode structure 160 may be formed by an inkjet printing method. Accordingly, since the method of manufacturing a solar cell forms the conductive electrode structure 160 by an inkjet printing method, it can simplify manufacturing processes and reduce manufacturing cost, in comparison with a case of forming the conductive electrode structure by a plating process.

Further, the method of manufacturing a solar cell in accordance with an embodiment of the present invention may form the conductive pattern 140 on the non-light receiving surface 114 of the substrate 110 by an inkjet printing method, form the solder paste 152 on the upper surface 142 of the conductive pattern 140, and heat-treat the solder paste 152 so that the solder paste 152 selectively covers the upper surface 142 while being self-aligned with the upper surface 142. Accordingly, since the method of manufacturing a solar cell in accordance with an embodiment of the present invention forms the solder layer 154 by self-aligning the solder layer 154 with the upper surface 142 of the conductive pattern 140, it can effectively form the solder layer 154 on the upper surface 142 of the conductive pattern 140 having a convex structure.

The method of forming a conductive electrode structure in accordance with the present invention may form the conductive pattern by applying the conductive paste on the substrate by an inkjet printing method and heat-treating the conductive paste. Accordingly, since the method of forming a conductive electrode structure in accordance with the present invention forms the conductive electrode structure by an inkjet printing method, it can simplify manufacturing processes and reduce manufacturing cost, in comparison with a case of forming the conductive pattern by a plating process.

The solar cell in accordance with the present invention may include the conductive electrode structure formed on the non-light receiving surface of the substrate, and the conductive electrode structure may include the conductive pattern formed by an inkjet printing method and the solder layer formed by being self-aligned with the upper surface of the conductive pattern. Accordingly, since the solar cell in accordance with the present invention includes the conductive pattern formed by an inkjet printing method and the solder layer formed by being self-aligned with the conductive pattern, it can provide a structure capable of simplifying manufacturing processes and reducing manufacturing cost, in comparison with a case having the conductive pattern formed by a plating process.

The method of manufacturing a solar cell in accordance with the present invention may include the conductive electrode structure bonded to the non-light receiving surface of the substrate, and the conductive pattern of the conductive electrode structure may be formed by an inkjet printing method. Accordingly, since the method of manufacturing a solar cell in accordance with the present invention forms the conductive electrode structure by an inkjet printing method, it can simplify manufacturing processes and reduce manufacturing cost, in comparison with a case of performing a plating process.

The foregoing description illustrates the present invention. Additionally, the foregoing description shows and explains only the preferred embodiments of the present invention, but it is to be understood that the present invention is capable of use in various other combinations, modifications, and environments and is capable of changes and modifications within the scope of the inventive concept as expressed herein, commensurate with the above teachings and/or the skill or knowledge of the related art. The embodiments described hereinabove are further intended to explain best modes known of practicing the invention and to enable others skilled in the art to utilize the invention in such, or other, embodiments and with the various modifications required by the particular applications or uses of the invention. Accordingly, the description is not intended to limit the invention to the form disclosed herein. Also, it is intended that the appended claims be construed to include alternative embodiments.

What is claimed is:

1. A method of forming a conductive electrode structure comprising:
applying a conductive paste on a substrate;
forming a conductive pattern having an outwardly convex shape by heat-treating the conductive paste; and
forming a solder layer to conformally cover the conductive pattern.

2. The method of forming a conductive electrode structure according to claim 1, wherein the applying the conductive paste is performed by using an inkjet printing method.

3. The method of forming a conductive electrode structure according to claim 1, wherein a paste including at least one of copper (Cu) and silver (Ag) is used as the conductive paste.

4. The method of forming a conductive electrode structure according to claim 1, wherein the forming the solder layer comprises:
applying a solder paste on the conductive pattern; and
heat-treating the solder paste.

5. The method of forming a conductive electrode structure according to claim 4, wherein the heat-treating the solder paste is performed to melt the solder paste so that the solder paste is formed to be self-aligned with an upper surface of the conductive pattern.

6. The method of forming a conductive electrode structure according to claim 4, wherein the applying the solder paste is performed by using an inkjet printing method, and the heat-treating the solder paste comprises reflowing the solder paste.

7. The method of forming a conductive electrode structure according to claim 1, further comprising forming a metal laminate pattern between the substrate and the conductive pattern, wherein the forming the metal laminate pattern comprises:
forming a first metal layer on the substrate; and
forming a second metal layer on the first metal layer.

8. A solar cell comprising:
a substrate having a light receiving surface, a non-light receiving surface opposite to the light receiving surface, and a PN impurity layer formed on the non-light receiving surface;
an insulating pattern which covers the non-light receiving surface and has a contact hole for exposing the PN impurity layer; and
a conductive electrode structure provided on the non-light receiving surface, wherein the conductive electrode structure comprises:
a metal laminate pattern bonded to the PN impurity layer through the contact hole;
a conductive pattern which covers the metal laminate pattern and has an outwardly convex shape; and
a solder layer which conformally covers the conductive pattern.

9. The solar cell according to claim 8, wherein the conductive pattern is formed by applying a conductive paste on the substrate.

10. The solar cell according to claim 8, wherein the solder layer is formed to be self-aligned with an upper surface of the conductive pattern.

11. The solder cell according to claim 8, wherein the metal laminate pattern comprises:
a first metal layer bonded to the PN impurity layer exposed through the contact hole; and
a second metal layer interposed between the first metal layer and the conductive pattern.

12. The solar cell according to claim 11, wherein the first metal layer is a layer for bringing the conductive pattern into ohmic contact with the PN impurity layer, and the second metal layer is a diffusion barrier layer for preventing metal ions of the conductive pattern from being diffused into the substrate.

13. The solar cell according to claim 8, wherein the PN impurity layer comprises:
an N-type impurity diffusion region; and
a P-type impurity diffusion region disposed in a region except the N-type impurity diffusion region, and the conductive electrode structure comprises:
a first electrode electrically bonded to the N-type impurity diffusion region through the contact hole; and
a second electrode electrically bonded to the P-type impurity diffusion region through the contact hole.

14. A method of manufacturing a solar cell comprising:
preparing a substrate having a light receiving surface and a non-light receiving surface opposite to the light receiving surface;
forming a PN impurity layer on the non-light receiving surface of the substrate;
forming an insulating pattern to cover the non-light receiving surface of the substrate; and
forming a conductive electrode structure on the non-light receiving surface, wherein the forming the conductive electrode structure comprises:
forming a metal laminate pattern bonded to the PN impurity layer through a contact hole;
forming a conductive pattern which covers the metal laminate pattern and has an outwardly convex shape; and
forming a solder layer to conformally cover the conductive pattern.

15. The method of manufacturing a solar cell according to claim 14, wherein the forming the conductive pattern comprises:
applying a conductive paste on the metal laminate pattern; and
heat-treating the conductive paste.

16. The method of manufacturing a solar cell according to claim 14, wherein the applying the conductive paste is performed by using an inkjet printing method.

17. The method of manufacturing a solar cell according to claim 14, wherein at least one of a copper paste and a silver paste is used as the conductive paste.

18. The method of manufacturing a solar cell according to claim 14, wherein the forming the solder layer comprises:
applying a solder paste on the conductive pattern; and
heat-treating the solder paste.

19. The method of manufacturing a solar cell according to claim 14, wherein the heat-treating the solder paste is performed to melt the solder paste so that the solder paste is formed to be self-aligned with an upper surface of the conductive pattern.

20. The method of manufacturing a solar cell according to claim 14, wherein the applying the solder paste is performed by using a screen printing method, and the heat-treating the solder paste comprises reflowing the solder paste.

21. The method of manufacturing a solar cell according to claim 20, wherein a paste including at least one of tin (Sn), silver (Ag), and nickel (Ni) is used as the solder paste.

22. The method of manufacturing a solar cell according to claim 14, wherein the forming the metal laminate pattern comprises:
forming a first metal layer which covers the non-light receiving surface while filling the contact hole; and
forming a second metal layer on the first metal layer.

23. The method of manufacturing a solar cell according to claim 22, wherein the forming the first metal layer comprises depositing an aluminum layer on the non-light receiving surface, and the forming the second metal layer comprises depositing a titanium tungsten layer on the non-light receiving surface.

24. The method of manufacturing a solar cell according to claim 14, wherein the preparing the substrate comprises preparing an N-type semiconductor substrate, and the forming the PN impurity layer comprises injecting P-type semiconductor impurity ions into the N-type semiconductor substrate.

25. The method of manufacturing a solar cell according to claim 14, wherein the preparing the substrate comprises preparing a transparent plate having light transmittance.
